(19) United States
(12) Patent Application Publication
(10) Pub. No.: US 2006/0254814 A1
(43) Pub. Date: Nov. 16, 2006

(54) Ground shield structure

(76) Inventors: Bouryi Sze, Hsin-Tien City (TW); Bob Cheng, Hsin-Tien City (TW); Chih-Long Ho, Hsin-Tien City (TW); Felix Kao, Hsin-Tien City (TW)

Correspondence Address: J.C. Patents, Suite 250, 4 Venture, Irvine, CA, 92618, US

(21) Appl. No.: 11/487,294

(22) Filed: Jul. 14, 2006

Related U.S. Application Data
(63) Continuation-in-part of application No. 10/681,471, filed on Oct. 7, 2003.

(30) Foreign Application Priority Data
Jul. 21, 2003 (TW) 92213288

(51) Int. Cl. H05K 9/00

(52) U.S. Cl. 174/350

(57) ABSTRACT

The invention is directed to an electric device featuring a ground shield structure. The electric device at lease comprises a plurality of first ground cells and a plurality of second ground cells. The first ground cells are distributed on a ground surface, wherein the first ground cell has at least one first outward section and at least one first inward section. The second ground cells are distributed on the ground surface, wherein the second ground cell has at least one second outward section and one second outward section of one second ground cell is compactly and complementarily embraced by one first inward section of one adjacent first ground cell.

### CROSS-REFERENCE TO RELATED APPLICATION

This application is a continuation-in-part of a prior application Ser. No. 10/681,471, filed Oct. 7, 2003. The prior application Ser. No. 10/681,471 claims the priority benefit of Taiwan application serial no. 92213288, filed on Jul. 21, 2003. All disclosure of the Taiwan application is incorporated herein by reference.

### BACKGROUND OF THE INVENTION

1. Field of Invention

The present invention relates to a ground shield structure. More particularly, the present invention relates to a compact and complementary ground shield structure (CCGSS) by a periodic arrangement.

2. Description of Related Art

In recent years, electronic techniques have been greatly and promptly developed. Particularly, since the semiconductor fabrication has been greatly developed, the integration for an integrated circuit (IC) device is continuously improved. Then, the size of an IC device is greatly reduced. Similarly, since the integration of an IC device is continuously improved, a circuit module, which usually is composed of several IC devices, can be formed by a single IC chip. In this manner, the function of the electronic product can be more and more powerful. Furthermore, the volume and the weight is more and more reduced.

In order to satisfy the circuit design for an IC device, and an inductor is necessary to be formed in the IC chip, the conventional technology is using the internal circuit of the IC chip to directly form the solenoid-like inductance coil, which is implemented over a substrate. As a result, when the current flows through the inductance coil, due to the flow of the current, an inducted current is generated. At the same time, the inducted current causes an eddy current on the substrate. It should be noted that occurrence of the eddy current then relatively decreases the inductance from the inductance coil.

In order to reduce the generation of eddy current, the conventional technology proposes a patterned ground shield (PGS) structure. FIG. 1 is a drawing, schematically illustrating the conventional ground shield structure. In FIG. 1, since several slots 120 of the ground shield structure 100 are used to divide the ground shield structure 100 into several ground strips 110. The ground strips 110 take a center point for reference, and are usually bent by an angle, such as 90 degrees, and then are disposed on the ground plane by a substantial irradiating arrangement. The conductive vias or other connecting pieces are used for electric connection. Moreover, since the slots 120 are designed to be very narrow, the electric field does not leak through the slots 120 to the region under the ground shield structure 100. The ground strips 110 are then used as the termination of the electric field.

It should be noted that since the slots 120 forms several open circuits in the ground shield structure 100, when an inductance coil (not shown) over the ground shield structure 100 is applied with a current, and the eddy current occurs on the ground shield structure 100, the slot 120 on the flow path of the eddy current E on the ground shield structure 100 can effectively cut the eddy current E. It can be reduced for the effect from decreasing the inductance quantity on the inductance coil due to the eddy current E. However, with respect to the ground shield structure 100, the ground strips 110 take a center point for reference, and are usually bent by an angle, such as 90 degrees, and then are arranged on the ground plane by a substantial irradiating arrangement. The foregoing ground shield structure 100 can only be used to remove the eddy current E, which is generated due to the inducting current on the ground shield structure 100. It cannot serve as the ground shield for the other microwave transmission device, such as transmission line, wave-guide, power divider, directional coupler, or microwave filter.

### SUMMARY OF THE INVENTION

The invention provides a ground shield structure, suitable for use of cutting the eddy current that is caused by the inducted current on the ground shield structure.

The invention provides a ground shield structure, suitable for use of increasing the slow-wave factor, so that the wave can slowly propagate and the needed area for the circuit layout is effectively reduced.

The invention further provides a ground shield structure, for increasing the inductance quantity and capacitance quantity of the ground shield structure in a unit area.

For at least achieving the foregoing objectives, the invention further provides a ground shield structure, suitable for use in a circuit structure. The ground shield structure includes multiple ground cells, which are distributed on a ground surface by a periodic and compactly complementary arrangement. A slot exists between two adjacent ground cells.

In accordance with the foregoing features, the ground shield structure is suitable for use in a circuit structure. The ground shield structure has a plurality of ground cells that are arranged on a ground plane periodically, compactly and complementarily. The slots between the ground cells are used to reduce the eddy current generated on the ground shield structure. The ground shield structure increases the slow-wave factor to slow the waves so that the area of the circuit layout can be decreased. Besides, the ground shield structure can reduce the energy loss of the inner circuit of the circuit structure and can increase the quantities of inductance and capacitance in per unit area thereon.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating the conventional ground shield structure.

FIGS. 2A-2D are drawings, schematically illustrating four different ground shield structures, according to preferred embodiments of this invention.

FIG. 3 is a drawing, schematically illustrating a fifth different ground shield structure, according to another preferred embodiment of this invention.

FIGS. 4A-4D are drawings, schematically illustrating the design rules of the ground shield structures, according to preferred embodiments of this invention.

FIGS. 5A-5C are drawings, schematically illustrating the electric devices, according to preferred embodiments of this invention.

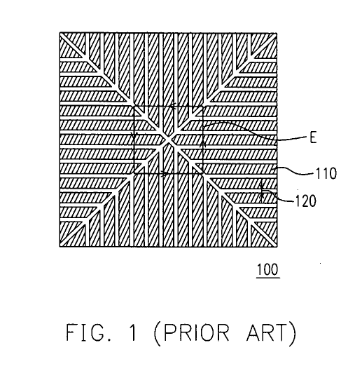

### DESCRIPTION OF THE PREFERRED EMBODIMENTS

The ground shield structure of the invention is suitable for use in a circuit structure, such as an integrated circuit, a printed circuit board, a chip package substrate, or other electronic devices, so as to provide the shielding function.

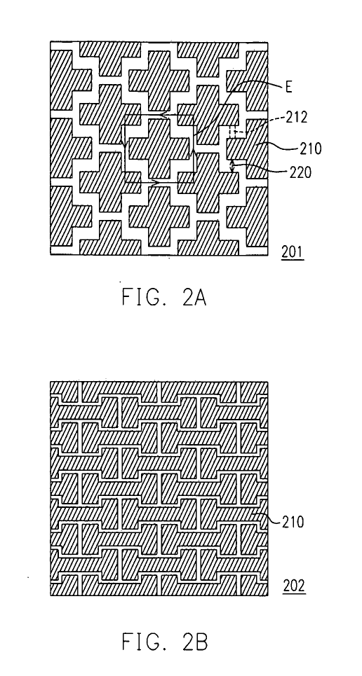

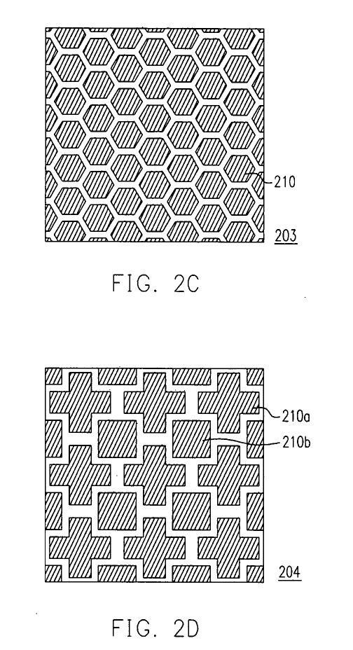

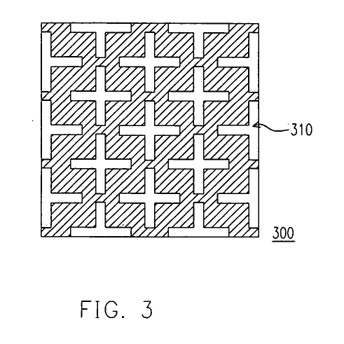

In FIG. 2A, a ground shield structure is shown, according to the invention. The ground shield structure 201 includes several ground cells 210, with identical profile, like a symbol of “+”. The ground cells 210 are distributed on a ground surface with a periodically and compactly complementary arrangement, wherein a slot 220 exists between two adjacent ground cells 210. It should be noted that the ground surface with the ground cells 210 is not limited to a planar surface. A curved surface is also applicable.

In addition, in order to electrically connect with the ground cells 210 and allow the ground cells 210 to be able to form a ground shield, the ground shield structure 201 further includes several interconnection members 212 (only one is shown by dashed line). The interconnection members 212 are respectively coupled between two adjacent ground cells 210. Moreover, when the ground shield structure 201 is formed by one of multiple circuit layers of the circuit structure, the vias in the circuit layers can be further used for connecting to the ground cells 210. As a result, the ground cells 210 can be indirectly and electrically coupled together through the circuit layers.

When the ground shield structure 201 is located under an inducted circuit (not shown), the current flowing through the inducting circuit would generated the inducted current. Accordingly, an eddy current E occurs on the ground shield structure 201 under the inducting circuit. However, in order to prevent the eddy current from occurring, the slot 220 on the flowing path of the eddy current E of the ground shield structure 201 can effectively cut the eddy current E. Then the affection on the inductance quantity of the inducting circuit from the eddy current E can be reduced. Further still, sine the slots 220 are designed to be very narrow, the electric field on the ground shield structure does not leak to the bottom region of the ground shield structure 201 through the slots 220. The ground cells 210 are used as the termination of the electric filed.

In FIGS. 2B-2D, they are drawings, schematically illustrating four different ground shield structures, according to preferred embodiments of this invention. In addition to the “+” shape of FIG. 2A for the ground cells 210, FIG. 2B shows another ground shield structure 202. The shape of the ground cells 210 in profile can be a dumbbell shape. Further in FIG. 2C, the ground shield structure 203 is shown. The cross-sectional profile of the ground cell 210 can also be like the beehive, that is a right hexagon. In addition to the ground cells 210 with a single cross-sectional profile, as shown in FIG. 2D, the ground shield structure 204 can include two or more different cross-section profiles 210a, 210b to be compact and complementary.

The cross-sectional profile of the ground cells of the ground shield structure in the invention include a single shape or multiple shapes as the example. However, under the consideration of periodical and compact arrangement, the ground cells of the ground shield structure in cross-sectional profile can be other shape, such as triangle, rectangle, regular polygon, or irregular polygon.

The ground cells of the ground shield structure in the invention can be formed by a patterning process with the positive manner or the negative manner.

FIG. 3 is a drawing, schematically illustrating a fifth different ground shield structure, according to another preferred embodiment of this invention. In FIG. 3, the ground shield structure 300 can be formed from a ground layer, which has been patterned, wherein a plurality of slots 310 are formed in periodic and regular arrangement. Further still, the in comparison with the ground cells 210 in FIG. 2A, these slots 310 have the identical cross-section profile or different cross-section profiles. However, it is still within the principle of compact and complementary arrangement. In addition, the ground shield structure 300 itself, that is, a ground surface, is not limited to a planar surface. It can be a curved surface, so that the ground shield structure 300 can enclose a transmission line.

The ground shield structures in various embodiments of the invention can be used in a circuit structure, such as an integrated circuit chip, a printed circuit board, or a die carrier in packaging, so as to reduce the area of a signal transmission device, such as transmission line, waveguide structure, power driver, a directional coupler, or microwave filter. As a result, the product quality can be effectively improved. Furthermore, the ground shield structure of the invention can also be used in a small-type electronic device, such as a low temperature ceramic capacitor (LTCC) and so on, so as to provide the ground shield function.

Referring to FIGS. 2A to 2D, the present invention provides an electric device featuring a novel ground shield structure design that has the principle of compact and complementary agreement. Here, the details of the principle would be described.

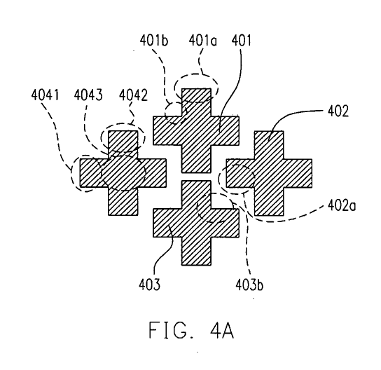

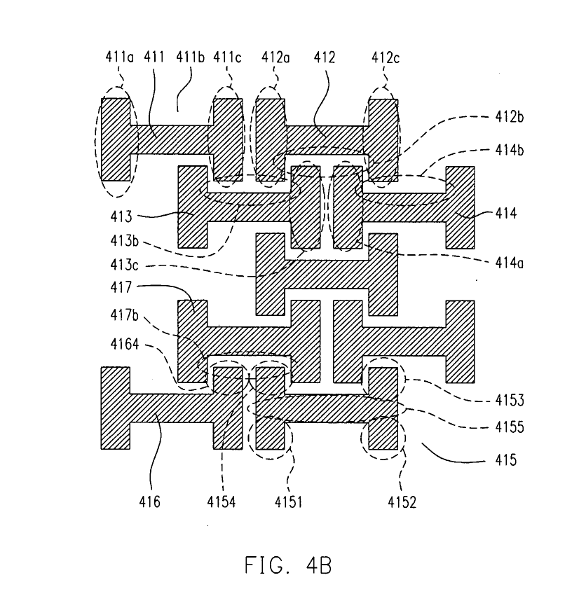

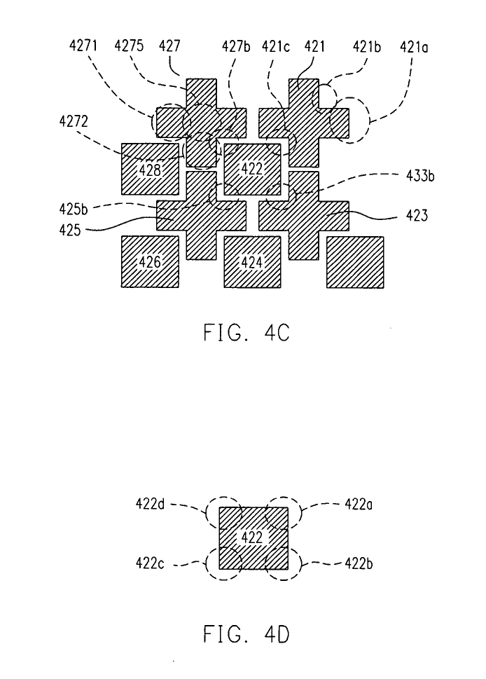

As shown in FIG. 4A, a cross-section profile 401 (or cell) has an outward section 401a and an inward section 401b. In the embodiments related to FIG. 4A, the repeated profiles (eg., 401, 402, and 403) result in a ground shield structure. In the ground shield structure, one outward section 402a of a profile 402 may be compact and complementary with one inward section 403b of another profile 403 that is adjacent to the profile 402.

There is an alternative way to explain the ideas about the embodiments related to FIG. 4A. Also see FIG. 4A. A cross-section profile 404 (or cell) has a main body 4043 and a plurality of protrusion portions (eg., 4041, 4042). The outer section of one protrusion portion is equivalent to an outward section mentioned above, and the space between two adjacent protrusion portions is equivalent to an inward section mentioned above. As a result, one protrusion portion of one profile 404 would be embraced in a compact and complementary way by one inward section of one adjacent profile 401 and one inward section of another one adjacent profile 403.

As shown in FIG. 4B, a cross-section profile 411 (or cell) has an outward section 411a and an inward section 411b, and the profile 411 also has another outward section 411c. In the embodiments related to FIG. 4B, the repeated profiles (eg., 411, 412, 413, and 414) result in a ground shield structure. In this ground shield structure, one profile 412 has an inward section 412b that embraces, in a compact and complementary way, both one outward section 413c of a profile 413 and one outward section 414a of a profile 414 while the profiles 413 and 414 are both adjacent to the profile 412. Additionally, one outward section 412a of the profile 412 is embraced, in a compact and complementary way, by an inward section 413b of the profile 413 while the other outward section 412c is embraced, in a compact and complementary way, by an inward section 414b of the profile 414.

There is an alternative way to explain the ideas about the embodiments related to FIG. 4B. Also see FIG. 4B. A cross-section profile 415 (or cell) has a main body 4155 and a plurality of protrusion portions (eg., 4151, 4152, 4153). The above-mentioned inward section is made of one protrusion portion 4151, one side section of a main body 4155, and another protrusion portion 4152 that is on the other side of the main body 4155 from the protrusion portion 4151. Consequently, the principle of compact and complementary agreement, that relates to the embodiments related to FIG. 4B, may be described as follows. One protrusion portion 4154 of one profile 415 and one protrusion portion 4164 of one adjacent profile 416 are embraced in a compact and complementary way by one inward section 417b of another adjacent profile 417.

As shown in FIG. 4C, there are two types of cross-section profile. One is a profile 421 (or cell) with both an outward section 421a and an inward section 421b while the other is a profile 422 (or cell) with no inward sections. See FIG. 4D. The profile 422 has four corners (eg., 422a, 422b, 422c, 422d). A corner is equivalent to one outward section of the profile 422.

In the embodiments related FIG. 4C, the repeated sets of these two types of profile (eg., 421/422, 423/424, 425/426, 427/428) result in a ground shield structure. Additionally, one profile 422 with no inward sections is surrounded, in a compact and complementary way, by four adjacent profiles (eg., 421, 423, 425, 427) that have both outward and inward sections. In other words, one inward section 421c of the profile 421 embraces one corner 422a of the profile 422 in a compact and complementary way; one inward section 423b of the profile 423 embraces one corner 422b of the profile 422 in a compact and complementary way; one inward section 425b of the profile 425 embraces one corner 422c of the profile 422 in a compact and complementary way; and one inward section 427b of the profile 427 embraces one corner 422d of the profile 422 in a compact and complementary way.

There is an alternative way to explain the ideas about the embodiments related to FIG. 4C. Also see FIG. 4C. A cross-section profile 427 (or cell) with inward sections has a main body 4275 and a plurality of protrusion portions (eg., 4271, 4272), and the space between two adjacent protrusion portions 4271, 2472 is an inward section mentioned above. Consequently, one corner of one adjacent profile 428 that has no inward sections would be embraced in a compact and complementary way by these two protrusion portions 4271, 2472 of the profile 427.

To summarize the general design rules of the ground shield structures of the present invention, the details are given as follows:
1. a ground shield structure may have one type of cross-section profile that has an inward section.
2. in the one-type-profile embodiments, the profile that has an inward section may have an outward section.
3. in the one-type-profile embodiments, one inward section of one profile may embrace, in a compact and complementary way, one outward section of its adjacent profile.
4. in the one-type-profile embodiments, the profile may have two or more outward sections.
5. in the one-type-profile embodiments, one inward section of one profile may embrace, in a compact and complementary way, two outward sections of two adjacent profiles.
6. a ground shield structure may have two types of cross-section profile, one has an inward section and the other has no inward sections.
7. in the two-type-profile embodiments, one profile that has no inward sections may be embraced, in a compact and complementary way, by inward sections of adjacent profiles.

Alternatively, to summarize the general design rules of the ground shield structures of the present invention, the details are given as follows:
1. a ground shield structure may have one type of cross-section profile that has a main body and a plurality of protrusion portions.
2. in the one-type-profile embodiments, two adjacent protrusion portions of one profile forms a space that is equivalent to an inward section.
3. in the one-type-profile embodiments, one protrusion portion of one profile would be embraced two inward sections from two different adjacent profiles.
4. a ground shield structure may further have two types of cross-section profile. One is a profile having a main body and a plurality of protrusion portions, and the other is a profile having no inward sections.
5. in the two-type-profile embodiments, two adjacent protrusion portions of one profile forms a space that is equivalent to an inward section. Two inward sections of two different adjacent profiles would embrace one corner of one adjacent profile that has no inward sections.

It should be noted that the shape of each profile may not be the same. In other words, in the one-type-profile embodiments, each profile may be different in shape from one another; or in the two-type-profile embodiments, for one type, each profile may be different in shape from one another while each profile of the other type may also be different in shape from one another.

It further should be noted that in any ground shield structures of the present invention, the profiles of a ground shield structure may be electrically isolated among one another. Or some of the profiles may be electrically connected by some interconnection members with one another. Or all of the profiles may be electrically connected by some interconnection members with one another.

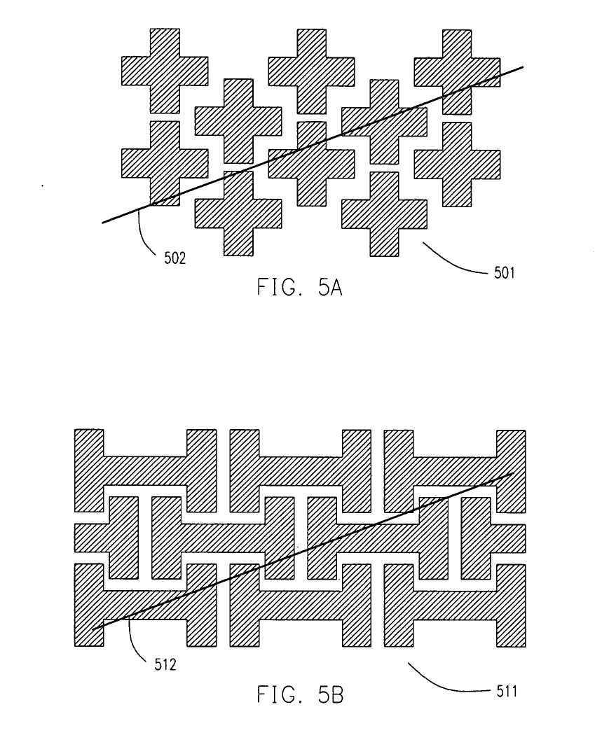

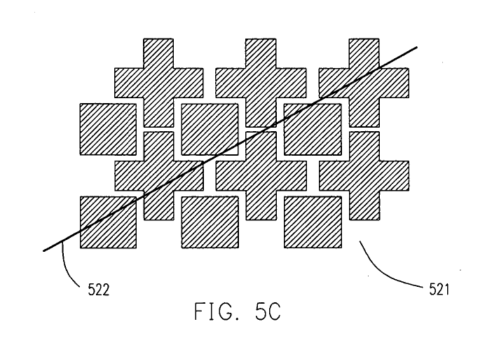

FIGS. 5A to 5C show other embodiments based on the above-mentioned ground shield structure designs. In FIG. SA, the embodiments of the present invention has a conductive line 502 and a ground shield structure 501, and the ground shield structure 501 has been described in the embodiments related to FIG. 4A. Additionally, the conductive line 502 passes through the area above the ground shield structure 501. Besides, the direction of the conductive line 502 depends on design engineers, and there is no constraint of the direction.

As shown in FIG. 5B, the embodiments has a conductive line 512 and a ground shield structure 511, and the ground shield structure 511 has been explained in the embodiments related to FIG. 4B. Additionally, the conductive line 512 passes through the area above the ground shield structure 511. Besides, the direction of the conductive line 512 depends on design engineers, and there is no constraint of the direction.

As shown in FIG. 5C, the embodiments has a conductive line 522 and a ground shield structure 521, and the ground shield structure 521 has been explained in the embodiments related to FIG. 4C and FIG. 4D. Additionally, the conductive line 522 passes through the area above the ground shield structure 521. Besides, the direction of the conductive line 522 depends on design engineers, and there is no constraint of the direction.

In summary, the ground shield structure of the invention with compact and complementary arrangement at least has several advantages as follows:
1. For the ground shield structure of the invention, the slot between the ground cells can increase the slow-wave factor to slow the waves so that the area of the circuit layout can be decreased.
2. For the ground shield structure of the invention, the ground shield structure can reduce the energy loss of the inner circuit of the circuit structure.
3. For the ground shield structure of the invention, it can increase the quantities of inductance and capacitance in per unit area thereon.
4. For the ground shield structure of the invention, the ground cells are arranged to be periodic and compactly complementary, so that it can be easily integrated into the integrated circuit chip, the printed circuit board, the die carrier in packaging, without the addition fabrication process.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. An electric device featuring a ground shield structure, at lease comprising:
a plurality of first ground cells distributed on a ground surface, wherein the first ground cell has at least one first outward section and at least one first inward section; and
a plurality of second ground cells distributed on the ground surface, wherein the second ground cell has at least one second outward section;
wherein one second outward section of one second ground cell is compactly and complementarily embraced by one first inward section of one adjacent first ground cell.

2. The electric device of claim 1, wherein the second ground cell further has at least one second inward section.

3. The electric device of claim 2, wherein one first outward section of one first ground cell is compactly and complementarily embraced by one second inward section of one adjacent second ground cell.

4. The electric device of claim 2, wherein the first ground cell further has at least one third outward section and the second ground cell further has at least one fourth outward section;

5. The electric device of claim 4, wherein one inward section of one first ground cell compactly and complementarily embraces two outward sections from two adjacent second ground cells of the first ground cell.

6. The electric device of claim 4, the first ground cell and the second ground cell are the same in shape.

7. The electric device of claim 1, wherein a slot exists between two adjacent ground cells.

8. The electric device of claim 1, wherein the ground cells are electrically isolated from one another.

9. The electric device of claim 1, wherein the first ground cell and the second ground cell are the same in shape.

10. The electric device of claim 1, further comprising a conductive line passing through the area above the ground surface.

11. An electric device featuring a ground shield structure, at lease comprising:
a plurality of first ground cells distributed on a ground surface, wherein the first ground cell has one first main body and at least two first protrusion portion; and
wherein two adjacent protrusion portions of one first ground cell embrace one protrusion portion of one adjacent first ground cell compactly and complementarily.

12. The electric device of claim 11, wherein the first ground cell has one first protrusion portion and one second protrusion portion at different sides of the main body.

13. The electric device of claim 12, wherein one first ground cell has one first protrusion portion, one second protrusion portion, and one side of the main body that form a first inward section embracing two protrusion portions of two adjacent first ground cells.

14. The electric device of claim 11, wherein the first ground cells are electrically isolated from one another.

15. The electric device of claim 11, wherein a slot exists between two adjacent first ground cells.

16. The electric device of claim 11, further comprising a conductive line passing through the area above the ground surface.

17. An electronic device, at least comprising:
a conductive line, wherein the conductive line passes by a ground surface;
a plurality of first ground cells distributed on the ground surface;
wherein the first ground cell has at least one first outward section and one first inward section;
wherein one first inward section of one first ground cell compactly and complementarily embraces one first outward of one adjacent first ground cell.

18. The electric device of claim 17, wherein the ground cells are electrically isolated from one another.

19. The electric device of claim 17, wherein a slot exists between two adjacent ground cells.

20. The electronic device of claim 17, wherein the first ground cell further has at one second outward section; wherein one first inward section of one first ground cell compactly and complementarily embraces two outward sections from two adjacent first ground cells.
